(19) United States
(12) Patent Application Publication
(10) Pub. No.: US 2013/0330542 A1
(43) Pub. Date: Dec. 12, 2013

(54) PHOTOVOLTAIC BACKSHEET

(71) Applicants: Yongzhong Wang, Tucson, AZ (US); Michael K. Martin, San Diego, CA (US)

(72) Inventors: Yongzhong Wang, Tucson, AZ (US); Michael K. Martin, San Diego, CA (US)

(21) Appl. No.: 13/896,010

(22) Filed: May 16, 2013

Related U.S. Application Data
(60) Provisional application No. 61/647,933, filed on May 16, 2012.

(51) Int. Cl. H01L 31/048; B32B 33/00

(52) U.S. Cl. CPC H01L 31/0487; B32B 33/00
USPC 428/341; 428/421; 428/412; 427/74

(57) ABSTRACT

Novel coating formulations and coating processes which have lower costs than TEDLA or KYNAR laminated backsheets, less curl than polyolefin laminated backsheets, excellent adhesion to encapsulant EVA, and better mar resistance on the surface facing the environment. In a preferred embodiment, the backsheet is formed by applying a distinct coating layer to each side of a film substrate. One coating layer is preferably a weather-resistant layer coated on the side of the substrate that will be exposed to the environment, while the other coating layer is a functional layer which provides excellent adhesion both to the substrate and to the EVA encapsulant layer.

### CROSS-REFERENCE TO RELATED APPLICATION(S)

The present application claims priority from U.S. Provisional Patent Application No. 61/647,933, filed May 16, 2012, entitled “PHOTOVOLTAIC BACKSHEET” naming inventors Yongzhong Wang and Michael K. Martin, which application is incorporated by reference herein in its entirety.

### FIELD OF THE DISCLOSURE

This disclosure, in general, relates to a photovoltaic backsheet, and in particular to a non-laminated asymmetrically coated backsheet.

### BACKGROUND

Photovoltaic or solar cells are used to produce electrical energy from sunlight. These solar cells are built from various semiconductor systems which must be protected from environmental effects such as moisture, oxygen, and UV light. The cells are usually jacketed on both sides by encapsulating layers of glass and/or plastic films forming a multilayer structure known as a photovoltaic module. FIG. 1 shows a prior art photovoltaic module 100. As shown in FIG. 1, a photovoltaic module 100 usually has a layer of glass 102 in the front and solar cells 104 surrounded by an encapsulant layer 106, typically ethylene vinyl acetate (EVA), which is bonded to the front glass and to a rear panel or sheet, which is called a backsheet 108. The backsheet provides the solar module with protection from moisture and other environmental damage, as well as electrical insulation.

Traditionally photovoltaic backsheets are made through a lamination process. Referring also to FIG. 1, a core substrate 110 such as polyethylene terephthalate (PET) film is laminated on both sides with fluoropolymer films 112, 114 such as TEDLAR (a PVF film from DuPont) or KYNAR (a PVDF film from Arkema) using adhesive layers 116. The PET acts as a mechanical support and dielectric insulation layer while the fluoropolymer films provide resistance against weathering.

Prior art laminated backsheets, however, suffer from a number of shortcomings. It is difficult to manufacture laminated structures that will not delaminate after years of exposure to the outdoors. Further, the manufacturing process for prior art laminated backsheets is expensive and time consuming. TEDLAR film is usually laminated to a core PET film one side at a time. Typically, the application of separate primers and adhesives is required before the actual lamination takes place. Also, the laminating adhesive needs time to harden (in some cases requiring several days). Immediately after lamination is completed, the adhesive is still soft and the laminated material is susceptible to damage such as the telescoping of material rolls.

Further, TEDLAR film is a soft material, which is easily maned by metal parts. During module production, handling, and transportation, modules with TEDLAR based backsheets can come in contact with metal parts of machinery which leaves marks or scratches on the backsheets. Some laminated backsheets have one layer of TEDLAR (or KYNAR) and one layer of polyolefin (or ethylene vinyl acetate layer) on a core PET film. Differences in thickness and elasticity of TEDLAR and the polyolefin film can cause such laminated backsheets to curl, which can cause module production issues.

It is also known in the prior art to use coatings, rather than laminated films, to produce backsheets. Typically a fluoropolymer coating is applied on both sides of a core PET film. However, the fluropolymer will usually have poor adhesion to an EVA encapsulant without some special treatment on the fluoro coating surface, such as chemical etching or a corona treatment. These types of surface treatments add cost and complexity to the manufacturing process. It is also known to use a fluoropolymer coating on only one side of a core PET film, with a layer of polyolefin film laminated to the other side of the PET. In this case, a lamination process is still needed, with the resulting problem of delamination. Curl issues also can arise due to the differences in tension induced by the thick layer of polyolefin film on only one side of the substrate.

As such, an improved photovoltaic backsheet would be desirable.

### SUMMARY OF THE INVENTION

A novel backsheet according to preferred embodiments of the present invention is produced using coating formulations and coating processes which have lower costs than TEDLA or KYNAR laminated backsheets, less curl than polyolefin laminated backsheets, excellent adhesion to encapsulant EVA, and better mar resistance on the surface facing the environment. In a preferred embodiment, the backsheet is formed by applying a distinct coating layer to each side of a film substrate. One coating layer is preferably a weather-resistant, opaque layer coated on the side of the substrate that will be exposed to the environment, while the other coating layer is a functional layer which provides excellent adhesion both to the substrate and to the EVA encapsulant layer.

The foregoing has outlined rather broadly the features and technical advantages of the present invention in order that the detailed description of the invention that follows may be better understood. Additional features and advantages of the invention will be described hereinafter. It should be appreciated by those skilled in the art that the conception and specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The present disclosure may be better understood, and its numerous features and advantages made apparent to those skilled in the art by referencing the accompanying drawings.

FIG. 1 shows a prior art photovoltaic module.

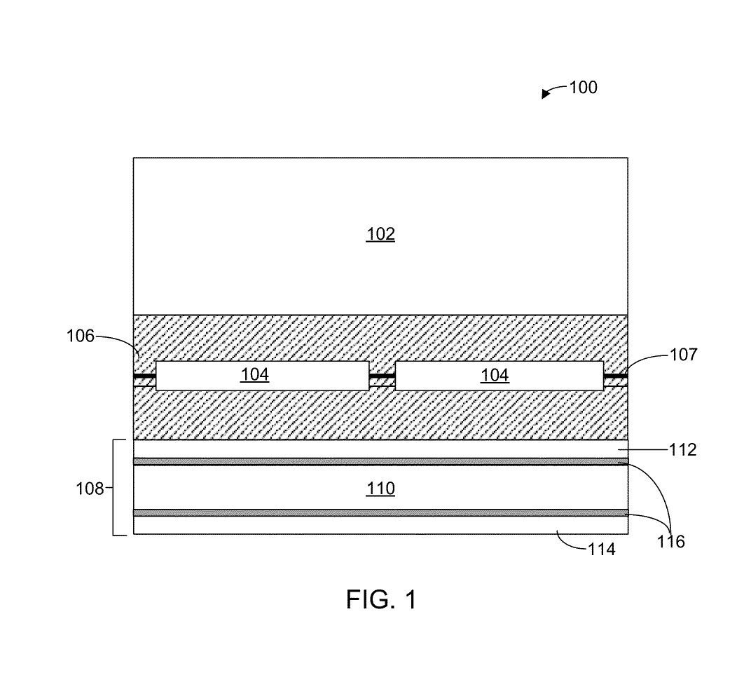

FIG. 2 is a schematic illustration of a cross-sectional view of a backsheet for a photovoltaic module according to a preferred embodiment of the present invention.

FIG. 3 is a flow chart showing the steps in a method of producing a backsheet for a photovoltaic module according to a preferred embodiment of the present invention.

The accompanying drawings are not intended to be drawn to scale. In the drawings, each identical or nearly identical component that is illustrated in various figures is represented by a like numeral. For purposes of clarity, not every component may be labeled in every drawing.

### DESCRIPTION OF THE DRAWINGS

The present invention provides a multilayer photovoltaic backsheet comprising a substrate with a different polymeric coating on either side of the substrate. The use of coatings instead of laminated layers provides for a manufacturing process that is faster, has fewer steps, and is more cost effective. Coatings can be tailored to provide excellent adhesion, without the problems of delamination seen in prior art laminated backsheets. Because the coatings can be thinner, the problem of curling is also minimized even when different coating compositions are used. Also because fluoropolymers are expensive and cause adhesion difficulties, in some embodiments only one fluoropolymer coating is used on the outer side of the substrate (toward the environment).

In a preferred embodiment, the coating layer on the side of the backsheet intended to be exposed to the environment is both opaque and weather/moisture resistant. As used herein, this coating will be referred to as the outer coating. Preferably the outer coating comprises a weather durable polymeric resin in solution or dispersion, as described in greater detail below. The inner coating, referring to the coating on the side of the substrate closest to the EVA encapsulant, is preferably transparent and provides excellent adhesion to the substrate and to the EVA encapsulant.

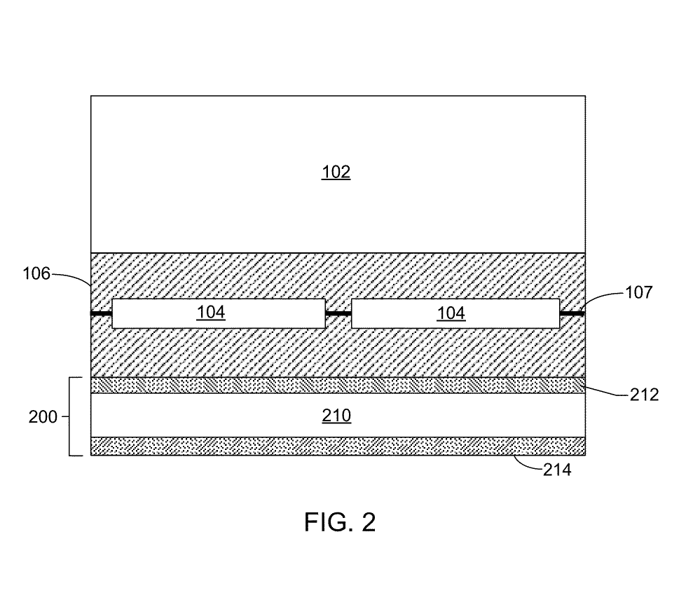

FIG. 2 is a schematic illustration of a cross-sectional view of a backsheet for a photovoltaic module according to a preferred embodiment of the present invention. Backsheet 200 comprises a polymeric film substrate 210 having a first side oriented toward the front surface of a photovoltaic module (toward the top glass layer) and a second side oriented toward the rear surface of the photovoltaic module (toward the environment on the back-side of the backsheet). A first inner coating 212 is applied to the inner surface of the substrate on the first side of the substrate, the inner coating preferably including a polymeric resin and a cross-linking agent. A second outer coating 214 is applied to the outer surface of the substrate on the second side of the polymeric film substrate. In a preferred embodiment, the outer coating 214 has a different composition from inner coating 212, preferably comprising fluoropolymer resin and a cross-linking agent. In a preferred embodiment, the fluoropolymer resin has an acid value of 1 to 25, more preferably from 1.5 to 5. Acid value is defined as the mass of potassium hydroxide (KOH) in milligrams that is required to neutralize one gram of chemical substance. The acid number is thus a measure of the amount of carboxylic acid groups or other acid groups in a chemical compound or in a mixture of compounds.

The polymeric film substrate can be any suitable polymeric film which provides sufficient electrical insulation and mechanical strength. Suitable polymeric film substrates include PET films such as MYLAR film from DuPont, HOSTAPHAN from Mitsubishi, or SKYROL from SKC. In other preferred embodiments, other polymeric films could be used including polyethylene naphthalate (PEN) film (available from DuPont), polycarbonate film, or a fluoroplastic film. A suitable polymeric film may be transparent, translucent, or opaque.

The outer coating layer according to preferred embodiments of the present invention is a weather-resistant polymeric resin that will prevent moisture from entering through the backside of the photovoltaic module. For example, a suitable polymeric resin for the outer coating could include acrylic resin, polyurethane, a fluoropolymer resin, or mixtures thereof. In a preferred embodiment, the polymeric resin is fluoropolymer resin. Suitable fluoropolymer resins include tetrafluoroethylene (TFE) and ethylene copolymer and chlorotrifluoroethylene (CTFE) and vinyl ether copolymer, fluoroethylene and vinyl ether copolymer (FEVE), and other fluoroethylene copolymer with acid and hydroxyl functional groups.

Applicants have discovered that adhesion between the fluoropolymer coating and the substrate is greatly increased when the fluoropolymer resin has at least one functional acid group. In other preferred embodiments, a fluoropolymer resin suitable for use in embodiments of the present invention will have a functional hydroxyl group or a combination of a functional acid group and a functional hydroxyl group. In a preferred embodiment, the fluoropolymer resin has an acid value of 1 to 25, more preferably from 1.5 to 5. An example of an acid-containing fluoropolymer is ZEFFLE GK series of TFE available from Daikin Industries. Another example of a fluoropolymer with suitable functional groups is the LUMIFLON series (e.g. LUMIFLON LF552) of FEVE available from Asahi Glass. In a specific example, a preferred fluoropolymer coating can be formed from a moderate molecular weight fluoroethylene and vinyl ether copolymer resin such as LUMIFLON LF552 (commercially available from Asahi Glass Co., Ltd.).

Preferably, a suitable fluoropolymer resin can be dispersed in water, or even more preferably dissolved in organic solvents.

If desired, various known pigments can be used to achieve a desired color or opacity by dispersing pigments and fillers into the fluoropolymer coating composition. Suitable pigments include titanium dioxide, silica, carbon black, aluminum oxide and the combination thereof. To make the fluoropolymer coating white, titanium oxide, zinc oxide, clays such as calcium carbonate, talc, silica, or aluminum could be added. To make the coating layer black, various carbon blacks can be added to the coating formulation. To make the coating other colors other than white or black, organic color pigments, inorganic pigments and dyes can be added to the coating formulation. To mix the pigments in the coating formulation, dispersing agent(s) can be added. Suitable dispersing agents such as DisperByk series dispersing agents are available from BykUSA. The type and amount of pigment will preferably be selected so that there will be no adverse effect on desirable properties of the fluoropolymer coating such as moisture/weather resistance.

Other additives such as leveling agents, catalysts, UV blocking agents, thermal stabilizers, and/or UV or light stabilizers can also be added to the fluoropolymer coating. While not generally needed, additional additives such as fiber glass and mineral fillers, anti-slip agents, plasticizers, nucleating agents, and the like, can also be used.

In some preferred embodiments, the fluoropolymer coating layer can be cross-linked. Suitable cross-linking agents can be chosen from isocyanate, aziridine, or any other suitable known cross-linking agent.

The fluoropolymer can be coated onto the polymeric film substrate using Meyer rod, slot die, gravure or other coating methods known in coating industry. The coating weight of the fluoropolymer coating preferably ranges from 10 g/m² to 100 g/m². More preferably, the coating weight of the fluoropolymer coating ranges from 20 g/m² to 50 g/m².

The inner coating according to embodiments of the present invention shows excellent adhesion to the substrate and to the EVA encapsulant. For example, a suitable polymeric resin for the inner coating could include polyester resin, acrylic resin, or polyurethane. Preferred polymeric resins suitable for use as an inner coating will have functional groups such as hydroxyl, carboxyl and amine groups, which will promote strong adhesion between the inner coating and both the substrate and the EVA encapsulate. In a preferred embodiment, the polymeric resin is selected from high molecular weight polyester resins having both acid and hydroxyl groups.

As with the outer coating, the inner coating can also include the variety of pigments, cross-linking agents, or any of the other additives described above.

Preferably, the inner coating materials can be dispersed in water, or even more preferably dissolved in organic solvents. The inner coating solution can be coated on a polymeric substrate using traditional coating methods such as Meyer rod, slot die, gravure, etc. The coating weight of the inner coating preferably ranges from 1 g/m² to 20 g/m². More preferably, the coating weight of the inner coating ranges from 2 to 10 g/m².

In a specific example, an inner coating can be formed from a high molecular weight, linear saturated copolyester resin such as VITEL 2700B and VITEL 2200B (commercially available from Bostik Findley) along with an isocyanate cross-linking agent. Significantly, VITEL 2700B and VITEL 2200B has an acid value of 1-3, which also serves to promote adhesion between the inner coating and both the substrate and the EVA encapsulant. In a preferred embodiment, a polymeric resin for use with embodiments of the present invention will have an acid value of 1 to 20, more preferably from 1.0 to 5.

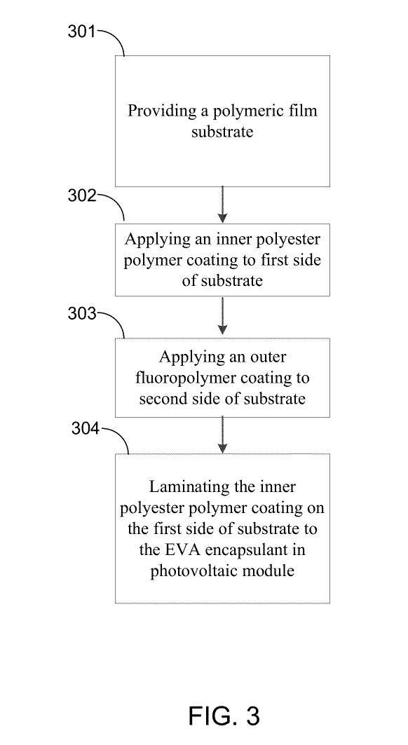

FIG. 3 is a flow chart showing the steps in a method of producing a backsheet for a photovoltaic module according to a preferred embodiment of the present invention. A preferred method of forming a backsheet for a photovoltaic module comprises providing a polymeric film substrate (step 301), such as a PET substrate as described above. When installed into a photovoltaic module, the polymeric film substrate will have a first side oriented toward the front surface of a photovoltaic module (toward the top glass layer) and a second side oriented toward the rear surface of the photovoltaic module (toward the environment on the back-side of the backsheet). Next, in step 302, a first inner coating can be applied to the first side of the polymeric film substrate (the side toward the EVA encapsulant) the first inner coating layer comprising polymeric resin and a cross-linking agent, as discussed above. In step 303, a second coating is applied to the second outer side of the polymeric film substrate, the second coating layer being different from the first coating layer and comprising fluoropolymer resin and a cross-linking agent. Preferably, the outer coating is formed from a fluoropolymer resin having an acid value of 1 to 25, more preferably from 1.5 to 5. Finally, in step 304, the backsheet (consisting of the substrate and the two coatings) is used to seal the backside of the photovoltaic module by laminating the inner coating to the EVA encapsulant.

The samples in the following examples might go though some or all following tests.

Mar Resistance Test

The sample surface was scratched with a penny coin. If a dark mark was left on the surface, the mar resistance was rated as 1; if no mark at all was left on the surface, mar resistance was rated 5. The higher the rating, the better the mar resistance of the surface.

Adhesion Test

The sample coating surface was cut with a cross-hatch tool. A tape was applied to the cut area. If coating was pulled off the substrate surface when tape was pulled away, the adhesion was rated as 1; if no coating was pulled off the surface, adhesion was rated at 5. The higher the rating, the better the coating adhesion to the substrate.

EVA Peel Test

The backsheet adhesion to EVA was rated 5 if the backsheet was hard to peel by hand and rated 1 if the backsheet was easy to peel by hand. The higher the rating, the better the backsheet adhesion to EVA. The backsheet adhesion to EVA was also measured by an INSTRON adhesion test if the sample was large enough. For those samples, the backsheet was cut into 1 inch wide sections for the peel test, and actual peel strength is given in pounds/in below.

The invention is further illustrated in the following examples:

### EXAMPLE 1

An outer coating slurry was made as follows: 26.3 grams of LUMIFLON LF552 (a fluoroethylene and vinyl ether copolymer, from Asahi Glass Co., Ltd.), 39.5 grams of TITONE D-918 (titanium dioxide from Sakai Chemical Ind. Co., Ltd) and 34.2 grams of Toluene were mixed together to make a paste. 22.2 grams of the above paste, 46.2 grams of LF552, 26.2 grams of Toluene, and 5.4 grams of LiofolHaerterUR7395-22 (an isocyanate homopolymer from Henkel used as a cross-linking agent) were mixed together to form the outer coating slurry. The outer coating slurry was coated with #30 Meyer rod on a 10 mil SG00L PET film (from SKC) and dried in an oven at 110° C. for 2 minutes having a dry coating weight of around 20 lb/ream. The outer coating layer was tested with a cross-hatch test and was found to have good adhesion on the PET film (adhesion rating of 5). LUMIFLON LF552 resin has an acid value of 5 mg KOH/g-polymer and an OH value of 52 mg KOH/g-polymer.

### COMPARATIVE EXAMPLE 1

An outer coating slurry was made as follows: 16.7 grams of LUMIFLON LF200 (a fluoroethylene and vinyl ether copolymer, from Asahi Glass Co., Ltd.), 40.0 grams of TITONE D-918, and 43.3 grams of Toluene were mixed together to make a paste. 21.9 grams of the above paste, 31.1 grams of LF200, 41.6 grams of Toluene, and 5.4 grams of LiofolHaerter UR 7395-22 were mixed together to form the outer coating slurry. The outer coating slurry was coated with #30 Meyer rod on a 10 mil SG00L PET film and dried in an oven at 110° C. for 2 minutes, having a dry coating weight of around 20 lb/ream. The outer coating layer was tested with a cross-hatch test and was found to have poor adhesion on the PET film (adhesion rating of 2). LUMIFLON LF200 resin has an acid value of 0 mg KOH/g-polymer and an OH value of 52 mg KOH/g-polymer.

### COMPARATIVE EXAMPLE 2

An outer coating slurry was made as follows: 25.0 grams of LUMIFLON LF600X (a fluoroethylene and vinyl ether copolymer, from Asahi Glass Co., Ltd.), 37.5 grams of TITONE D-918, and 37.5 grams of Toluene were mixed together to make a paste. 23.4 grams of the above paste, 35.8 grams of LF600X, 35.4 grams of Toluene, and 5.4 grams of LiofolHaerter UR 7395-22 were mixed together to form the outer coating slurry. The outer coating slurry was coated with #30 Meyer rod on a 10 mil SG00L PET film and dried in an oven at 110° C. for 2 minutes, having a dry coating weight of around 20 lb/ream. The outer coating layer was tested with a cross-hatch test and was found to have poor adhesion on the PET film (adhesion rating of 2). LUMIFLON LF600X resin has an acid value of 0 mg KOH/g-polymer and an OH value of 57 mg KOH/g-polymer.

### COMPARATIVE EXAMPLE 3

An outer coating slurry was made as follows: 30.1 grams of LUMIFLON LF910LM (a fluoroethylene and vinyl ether copolymer, from Asahi Glass Co., Ltd.), 30.1 grams of TITONE D-918, and 39.8 grams of Toluene were mixed together to make a paste. 29.1 grams of the above paste, 22.8 grams of LF910LM, 42.7 grams of Toluene, and 5.4 grams of LiofolHaerter UR 7395-22 were mixed together to form the outer coating slurry. The outer coating slurry was coated with #30 Meyer rod on a 10 mil SG00L PET film and dried in an oven at 110° C. for 2 minutes, having a dry coating weight of around 20 lb/ream. The outer coating layer was tested with a cross-hatch test and was found to have poor adhesion on the PET film (adhesion rating of 2). LUMIFLON LF910LM resin has an acid value of 0 mg KOH/g-polymer and an OH value of 100 mg KOH/g-polymer.

TABLE 1
Acid Value and Coating Adhesion.

| | | Comparative | Comparative | Comparative |
|---|---|---|---|---|
| | Example 1 | Example 1 | Example 2 | Example 3 |
| Acid value (mg | 5 | 0 | 0 | 0 |
| KOH/g-polymer) | | | | |
| First coating | 5 | 2 | 2 | 2 |
| adhesion | | | | |

EXAMPLE 1 and COMPARATIVE EXAMPLES 1-3 show that the inventive outer coating layer containing a fluoropolymer with acid groups demonstrates better coating adhesion to PET film substrate than a coating containing fluoropolymer without acid groups.

### EXAMPLE 2

An outer coating slurry was made as follows: 65.0 grams of ZEFFLE GK-570 (a tetrafluoroethylene and ethylene copolymer, from Daikin America), 5.8 grams of DISPERBYK 111 (from BYK USA), 137.3 grams of n-butyl acetate, and 192.0 grams of TI-PURE R960 (titanium dioxide from DuPont) were mixed together to form a paste. 56.8 grams of the above paste, 33.0 grams of GK-570, 4.4 grams of n-butyl acetate, and 5.8 grams of LiofolHaerter UR 7395-22 were mixed together for the outer coating slurry. The outer coating slurry was coated with a Meyer rod on a 10 mil SKC SG00L PET film and dried in an oven at 120 C for 2 minutes, having a coating weight of around 12 lb/ream. The outer coating layer was tested with a cross-hatch test and was found to have good adhesion on the PET film (adhesion rating of 5). ZEFFLE GK570 resin has an acid value of 1.5-4.5 mg KOH/g-polymer and an OH value of 55-65 mg KOH/g-polymer.

An inner coating solution can be made as follows: 50-60 grams of VITEL V2200B resin (polyester resin from Bostik), 80 to 120 grams of ethyl acetate, 30 to 60 grams of methyl ethyl ketone, 0.5 to 1.2 grams of TINUVIN 292, and 0.5 to 1.2 grams of TINUVIN 384-2 (both types of TINUVIN from Ciba Chemicals) mixed together until VITEL resin is dissolved. Add 5.0 to 8.0 grams of LiofolHaerter UR 7395-22 to the solution to make a suitable inner coating solution.

An inner coating solution made as described above was coated on the opposite side of the PET film from the above outer coating layer to form a backsheet with a coating weight of 4 lb/ream. The inner coating layer had very good adhesion on the PET film (adhesion rating of 5). VITEL V2200B resin is a polyester resin with an acid value of 1-3 mg KOH/g-polymer and an OH value of 3-5 mg KOH/g-polymer.

The backsheet of Example 2 had a VLT of around 17. The backsheet was laminated to an encapsulant layer of EVA to form a structure as follows: outer coating layer/PET/inner coating layer/EVA/Glass. It was found the inventive backsheet of Example 2 had excellent adhesion to EVA, as shown in Table 2 below.

### EXAMPLE 3

Example 3 was identical to Example 2 except that the outer coating slurry was coated with a Meyer rod on a 10 mil SG00L PET film having a coating weight of around 20 lb/ream. The backsheet had a VLT of 12. The backsheet was laminated to an encapsulant layer of EVA to form a structure as follows: outer coating layer/PET/inner coating layer/EVA/Glass. It was found the inventive backsheet of Example 3 had excellent adhesion to EVA, as shown in Table 2 below.

### EXAMPLE 4

An outer coating slurry was made as follows: 82.9 lbs. of ZEFFLE GK-570, 2.5 lbs. of DISPERBYK 111, 102.3 grams of ethyl acetate, and 250.0 lbs of TI-PURE R-960 were mixed together to get a paste. 437.7 lbs. of this paste, 33.7 lbs. of ethyl acetate, and 341.3 lbs. of ZEFFLE GK-570 were mixed together to form the outer coating slurry. The outer coating slurry was coated with slot die coating machine on a 10 mil SKC SG001 PET film and dried in an oven, having a drying coating weight of 22 lb/ream.

An inner coating solution identical that used in Example 2 was coated with a Meyer rod on the PET film side opposite the outer coating layer to form a backsheet. The backsheet of Example 4 had a VLT of around 11. The backsheet was laminated to an encapsulant layer of EVA to form a structure as follows: outer coating layer/PET/inner coating layer/EVA/Glass. It was found the inventive backsheet of Example 4 had excellent adhesion to EVA, as shown in Table 2 below.

### COMPARATIVE EXAMPLE 4

Comparative Example 4 was a commercial grade of TPT backsheet, where T was TEDLAR film and P was a PET film. TEDLAR film was laminated to the PET film on both sides to make a conventional TPT backsheet.

### COMPARATIVE EXAMPLE 5

Comparative Example 5 was a commercial grade of TPE backsheet, where T was TEDLAR film, P was a PET film, and E was polyolefin or ethylene vinyl acetate polymer. TEDLAR film and polyolefin film were laminated to either side of the PET film to make a conventional TPE backsheet.

The test results for the inventive backsheets of Examples 2-4 and for the comparative backsheets (Comparative Examples 4-5) are illustrated in following table:

TABLE 2
Test Results.

| | | | | 1^{st} coating |
|---|---|---|---|---|
| | Backsheet | Backsheet | Backsheet | layer |
| | TEDLAR | Lamina- | EVA | Mar |
| | layers | tion | adhesion | Resistance |
| Example 2 | No | No | 5 | 5 |
| Example 3 | No | No | 5 | 5 |
| Example 4 | No | No | 5 | 5 |
| Comparative Example 4 | 2 | Yes | 5 | 2 |
| Comparative Example 5 | 1 | Yes | 5 | 2 |

EXAMPLES 2-4 showed that the inventive backsheets can be coated on both sides without lamination. This will eliminate any shortcomings with lamination process. The inventive backsheets also eliminate the use of TEDLAR films. This results in a cost saving for the inventive backsheets and photovoltaic modules using them. The inventive backsheets also had better mar resistance than the comparative backsheets with TEDLAR layers.

### EXAMPLE 5

A layer of PV 2111 TEDLAR was laminated onto one side of 10 mil SG00L PET film. The other side of the PET surface was then coated with the inner coating solution used in Example 2. The dry coating weight of the inner coating layer was around 4 lb/ream. The inner coating side of the film was laminated with EVA (First 806 EVA) to glass. This sample was used to test inner coating layer adhesion to the EVA encapsulant. Sample portions were then put into an environmental chamber at 85° C. and 85% relative humidity (RH) for 500 hours and 1000 hours. The backsheet peel strength was measured with an INSTRON peel tester.

### COMPARATIVE EXAMPLE 6

A commercially available backsheet was laminated to EVA as in Example 5. This sample was put the same environmental chamber as Example 5 for 500 hours and 1000 hours.

The peel strengths of Example 5 and Comparative Example 6 are shown in the table below:

TABLE 3
Peel Strength.

| | Initial Peel | 500 hours Peel | 1000 hours Peel |
|---|---|---|---|
| | (lb/in) | (lb/in) | (lb/in) |
| Example 5 | 40 | 30 | 34 |
| Comparative | 34 | 2 | 17 |
| Example 6 | | | |

As shown in Table 3, Example 5 with the inventive inner coating layer showed better initial peel strength than Comparative Example 6 (which used a commercially available backsheet). The inner coating layer in Example 5 also showed much better durability under damp heat condition (85° C./85% RH) than that of the Comparative Example 6 as the peel strength of Example 5 stayed stable during the damp heat test period. When using a PET substrate, the PET substrate itself begins to degrade after 1000 hours, making it difficult to get adhesion data beyond 1000 hours.

### EXAMPLE 6

An inner coating solution identical to the one used in Example 2 was coated onto a 5 mil PEN substrate (TEONEX Q83) at around 4 lb/ream dry coating weight. PEN was used as a substrate for this testing because it is much more durable than PET, thus making it possible to gather adhesion data beyond the limits of a PET substrate. The PEN substrate with the inner coating layer was laminated to glass with Saint-Gobain LIGHTSWITCH EVA. The initial peel strength of the sample was measured to be 56.7 lb/in. Sample portions were then subjected to a pressure cooker test at around 127° C. and 1.5 atm for 24 hours, 48 hours, 72 hours, and 96 hours. The peel strength of the inner coating layer was rated by hand peel as shown in the table below.

TABLE 4
Peel Strength.

| | 24 hours | 48 hours | 72 hours | 96 hours |
|---|---|---|---|---|
| Example 6 | 5 | 5 | 5 | 2* |

*At 96 hours the PEN substrate became brittle.

The pressure cooker test indicated that the inner coating layer was very durable under hydrolysis and maintained excellent adhesion during the test. Most PET films become brittle after 48 hours in a pressure cooker test. The inventive inner coating layer was thus more durable than the PET film typically used in PV backsheets. From this, it can be expected that the inventive inner coating layer will not be the weak-link in actual outdoor use of a photovoltaic module using a backsheet according to embodiments of the present invention. Instead the conventional PET substrate would be expected to fail before the adhesion of the inner coating layer fails.

The present invention has broad applicability and can provide many benefits as described and shown in the examples above. The embodiments will vary greatly depending upon the specific application, and not every embodiment will provide all of the benefits and meet all of the objectives that are achievable by the invention. Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention. After reading the specification, skilled artisans will appreciate that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present). Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

Although the present invention and its advantages have been described in detail, it should be understood that various changes, substitutions and alterations can be made to the embodiments described herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

We claim as follows:

1. A backsheet for a photovoltaic module comprising:
a polymeric film substrate having a first side to be oriented toward the front surface of the photovoltaic module and a second side to be oriented away from the photovoltaic module;
an inner coating on the first side of the polymeric film substrate, the inner coating layer comprising polymeric resin and a cross-linking agent; and
an outer coating on the second side of the polymeric film substrate, the outer coating layer being different from the inner coating layer and comprising fluoropolymer resin and a cross-linking agent, wherein the fluoropolymer resin has an acid value of 1 to 25.

2. A backsheet for a photovoltaic module comprising:
a polymeric film substrate having a first side oriented to be oriented toward the front surface of the photovoltaic module and a second side to be oriented away from the photovoltaic module;
an inner coating on the first side of the polymeric film substrate, the inner coating layer comprising polymeric resin and cross-linking agent; and
an outer coating on the second side of the polymeric film substrate, the outer coating layer being different from the inner coating layer and comprising fluoropolymer resin and a cross-linking agent, wherein the fluoropolymer resin has at least one functional acid group.

3. A method of forming a backsheet for a photovoltaic module, the method comprising:
providing a polymeric film substrate having a first side to be oriented toward the front surface of the photovoltaic module and a second side to be oriented away from the photovoltaic module;
applying an inner coating to the first side of the polymeric film substrate, the inner coating layer comprising polymeric resin and a cross-linking agent; and
applying an outer coating to the second side of the polymeric film substrate, the outer coating layer being different from the inner coating layer and comprising fluoropolymer resin and a cross-linking agent, wherein the fluoropolymer resin has an acid value of 1 to 25.

4. The backsheet of claim 1 in which the polymeric film substrate is an unlaminated film.

5. The backsheet of claim 1 in which the polymeric film substrate is an unlaminated film having a first functional coating on a first side which does not include a fluoropolymer, a second coating on a second side which does include a fluoropolymer, and which does not include an adhesive layer between the substrate and the first functional coating or between the substrate and the second coating.

6. The backsheet of claim 1 in which the polymeric film substrate comprises polyethylene tetrephthalate (PET) film.

7. The backsheet of claim 1 in which the polymeric film substrate comprises polyethylene naphthalate (PEN) film.

8. The backsheet of claim 1 in which the polymeric film substrate comprises polycarbonate or fluoroplastic film.

9. The backsheet of claim 1 in which the inner coating comprises a functional coating providing an adhesion to ethylene vinyl acetate of at least 5 N/m.

10. The backsheet of claim 1 in which the inner coating comprises a polymeric resin with at least one hydroxyl, carboxyl, or amine functional group.

11. The backsheet of claim 1 in which the inner coating comprises a polymeric resin having an acid value of 1.0 to 20.

12. The backsheet of claim 1 in which the inner coating comprises a polymeric resin having an acid value of 1.0 to 5.

13. The backsheet of claim 1 in which the inner coating comprises polyester resin, acrylic resin and/or polyurethane.

14. The backsheet of claim 1 in which the inner coating comprises a high molecular weight polyester resin with at least one acid and one hydroxyl functional group.

15. The backsheet of claim 1 in which the inner coating has a coating weight in the range of 1 g/m² to 20 g/m².

16. The backsheet of claim 1 in which the inner coating has a coating weight in the range of 2 g/m² to 10 g/m².

17. (canceled)

18. The backsheet of claim 1 in which the outer coating comprises an opaque coating containing a weather durable polymeric resin in solution or dispersion.

19. The backsheet of claim 1 in which the outer coating comprises a fluoropolymer resin.

20. The backsheet of claim 1 in which the outer coating comprises: a fluoropolymer resin of tetrafluoroethylene (TFE) and ethylene copolymer; or a fluoropolymer resin of chlorotrifluoroethylene (CTFE) and vinyl ether copolymer.

21. (canceled)

22. The backsheet of claim 1 in which the outer coating has a coating weight in the range of 10 g/m² to 100 g/m².

23. The backsheet of claim 1 in which the outer coating has a coating weight in the range of 20 g/m² to 50 g/m².

24-61. (canceled)
